(19) United States
(12) Patent Application Publication
(10) Pub. No.: US 2002/0086547 A1
(43) Pub. Date: Jul. 4, 2002

(54) Etch pattern definition using a CVD organic layer as an anti-reflection coating and hardmask

(75) Inventors: David S. Mui, Fremont, CA (US); Wei Liu, San Jose, CA (US); Thorsten Lill, Santa Clara, CA (US); Christopher Dennis Bencher, San Jose, CA (US); Yuxiang May Wang, Palo Alto, CA (US)

Correspondence Address: MAYER, FORTKORT & WILLIAMS, PC, 251 NORTH AVENUE WEST, 2ND FLOOR, WESTFIELD, NJ, 07090, US

(73) Assignee: Applied Materials, Inc.

(21) Appl. No.: 09/905,172

(22) Filed: Jul. 13, 2001

Related U.S. Application Data
(60) Provisional application No. 60/183,507, filed on Feb. 17, 2000.

(51) Int. Cl. H01L 21/302; H01L 21/461

(52) U.S. Cl. 438/710

(57) ABSTRACT

A multilayer antireflective hard mask structure is disclosed. The structure comprises: (a) a CVD organic layer, wherein the CVD organic layer comprises carbon and hydrogen; and (b) a dielectric layer over the CVD organic layer. The dielectric layer is preferably a silicon oxynitride layer, while the CVD organic layer preferably comprises 70-80% carbon, 10-20% hydrogen and 5-15% nitrogen. Also disclosed are methods of forming and trimming such a multilayer antireflective hard mask structure. Further disclosed are methods of etching a substrate structure using a mask structure that contains a CVD organic layer and optionally has a dielectric layer over the CVD organic layer.

This application is related to Provisional Application Serial No. 60/183,507, filed Feb. 17, 2000 and entitled “Method of Depositing Amorphous Carbon Layer”.

### BACKGROUND OF THE INVENTION

1. Field of the Invention

The present invention relates to anti-reflection coatings and hard masks for use in defining etch patterns within an underlying substrate structure.

2. Brief Description of the Background Art

Integrated circuit manufacturing processes often involve the creation of etch patterns in various materials by selective etching. For example, trenches are often made in a substrate such as silicon to provide isolation between individual devices or to provide capacitive charge storage or to define the gate for a transistor.

Usually these etch patterns are created by providing a mask upon the material within which the etch pattern is to be made. The material is then etched through apertures in the mask. The resulting etch pattern may be subsequently filled with appropriate materials. For example, where the etch pattern is a trench, the trench may be filled with insulating material to facilitate inter-device isolation. If the trench is to be used for capacitive storage, it may be lined with one or more layers of conductive material.

Photoresists are typically employed at some point during the etching process. In general, the smaller the feature size that is required, the thinner the photoresist layer is required to be. Unfortunately, the thickness of a given photoresist layer is frequently limited by the thickness of the material that is to be etched and the selectivity that exists between the photoresist and the material that is to be etched.

The need for smaller feature sizes has also resulted in an increase in the use of antireflective coatings (including phase shift layers, absorption layers, and layers that provide both phase shift and absorption functions). In the absence of an antireflective coating, standing waves can be generated within the photoresist during the exposure process. These standing waves can cause, for example, sinusoidal undulations at the edges of the photoresist features that are produced, adversely affecting resolution.

### SUMMARY OF THE INVENTION

The above and other demands of present day integrated circuit etching processes are addressed by the present invention.

According to an embodiment of the invention, a multiplayer antireflective hard mask structure is provided. The structure comprises: (a) a CVD organic layer, wherein the CVD organic layer comprises carbon and hydrogen; and (b) a dielectric layer over the CVD organic layer. The dielectric layer is preferably a silicon oxynitride layer, while the CVD organic layer preferably comprises 70-80% carbon, 10-20% hydrogen and 5-15% nitrogen.

According to another embodiment of the invention, a method of forming the above multilayer antireflective hard mask structure is provided. The method comprises: (a) providing a substrate structure; (b) depositing a CVD organic layer over the substrate structure; (c) depositing a dielectric layer over the CVD organic layer; (d) providing a patterned organic photoresist layer over the dielectric layer; (e) etching the dielectric layer through apertures in the patterned photoresist layer in a first plasma etching step until apertures are formed in the dielectric layer; and (f) etching the CVD organic layer through the apertures in the dielectric layer in a second plasma etching step until apertures are formed in the CVD organic layer.

Preferably, the first plasma etching step is conducted using a plasma source gas that comprises a halogen containing species (e.g., CF₄, C₂F₆, etc.) and the second plasma etching step is conducted using a plasma source gas that comprises an oxygen containing species (e.g., O₂). The CVD organic layer is preferably deposited by a plasma enhanced chemical vapor deposition process using a feed stream that comprises a hydrocarbon species (such as propylene) and, optionally, N₂.

According to another embodiment of the invention, a process for trimming a mask feature is provided. The method comprises: (a) providing one or more mask features on a substrate structure, wherein each mask feature comprises a CVD organic layer and a dielectric layer disposed over the CVD organic layer, such that sidewall portions of the CVD organic layer are exposed; and (b) preferentially etching the exposed sidewall portions of the CVD organic layer using a plasma etching process, such that the width of the one or more mask features is reduced at the substrate. Preferably, the CVD organic layer is etched using a plasma source gas that comprises an oxygen containing species such as O₂.

According to another embodiment of the invention, a method of etching a substrate structure is provided which comprises: (a) providing a substrate structure; (b) providing a CVD organic layer, which has apertures formed therein, over the substrate structure; and (c) etching the substrate structure through the apertures by a plasma etching process.

According to yet another embodiment of the invention, a method of etching a substrate structure is provided which comprises: (a) providing a substrate structure; (b) providing a patterned multilayer mask structure over the substrate structure, wherein the patterned multilayer mask structure has apertures and comprises: (i) a CVD organic layer and (b) a dielectric layer over the CVD organic layer; and (c) etching the substrate structure through the apertures by a plasma etching process. Typically, remnants of the patterned multilayer mask structure (which are normally portions of the CVD organic layer, because the thickness of the dielectric layer is preferably selected such that it is etched away during the plasma etching of the substrate) are removed after the substrate structure is etched using a plasma etching process, which preferably comprises an oxygen containing species such as O₂.

In some preferred embodiments, the substrate structure comprises a silicon layer, which layer is etched in the plasma etching process. As one example, the substrate structure can comprise a single crystal silicon layer (1^{st} layer), an oxide layer (2^{nd} layer) over the single crystal silicon layer (1^{st} layer), a doped polycrystalline silicon layer (3^{rd} layer) over the oxide layer (2^{nd} layer), and, in this example, a native oxide layer (4^{th} layer) over the doped polycrystalline silicon layer (3^{rd} layer). The native oxide layer and the doped polycrystalline silicon layer are then etched by the plasma etching process. As another example, the substrate structure can comprise a single crystal silicon layer, an oxide layer over the single crystal silicon layer and a silicon nitride layer over the oxide layer. Each of these layers is then etched by the plasma etching process.

One advantage of the present invention is that a structure is provided, which has both antireflective properties and highly effective hard mask properties.

Another advantage of the present invention is that masking structure is provided whose formation requires only a very thin photoresist layer, thus improving pattern resolution.

Another advantage of the present invention is that a masking structure is provided that can be effectively trimmed to decrease the critical dimensions of the features being etched.

Another advantage is that the CVD organic layer can be trimmed with a dielectric antireflective coating (DARC) or thin silicon oxide layer as the mask to achieve smaller critical dimensions of the features being etched.

Yet another advantage of the present invention is that a masking structure is provided that can easily be removed.

The above and other embodiments and advantages of the present invention will become apparent to those of ordinary skill in the art upon reading the detailed description and claims to follow.

### BRIEF DESCRIPTION OF THE DRAWINGS

FIGS. 1A through 1E are schematic partial cross-sectional views illustrating an etching process according to an embodiment of the invention.

FIGS. 2A and 2B are schematic partial cross-sectional views illustrating the trimming of a CVD organic layer according to an embodiment of the invention.

FIGS. 3A through 3E are schematic partial cross-sectional views illustrating an etching process according to an embodiment of the invention.

FIGS. 4A through 4C are schematic partial cross-sectional views illustrating another etching process according to another embodiment of the invention.

### DETAILED DESCRIPTION OF PREFERRED EMBODIMENTS OF THE INVENTION

As a preface to the detailed description, it should be noted that, all percentages (%) listed for gas constituents are % by volume, and all ratios listed for gas constituents are volume ratios.

The term “selectivity” is used to refer to a) a ratio of etch rates of two or more materials and b) a condition achieved during etch when etch rate of one material is increased in comparison with another material.

The present invention now will be described more fully hereinafter with reference to the accompanying drawings, in which preferred embodiments of the present invention are shown. This invention may, however, be embodied in different forms and should not be construed as limited to the embodiments set forth herein.

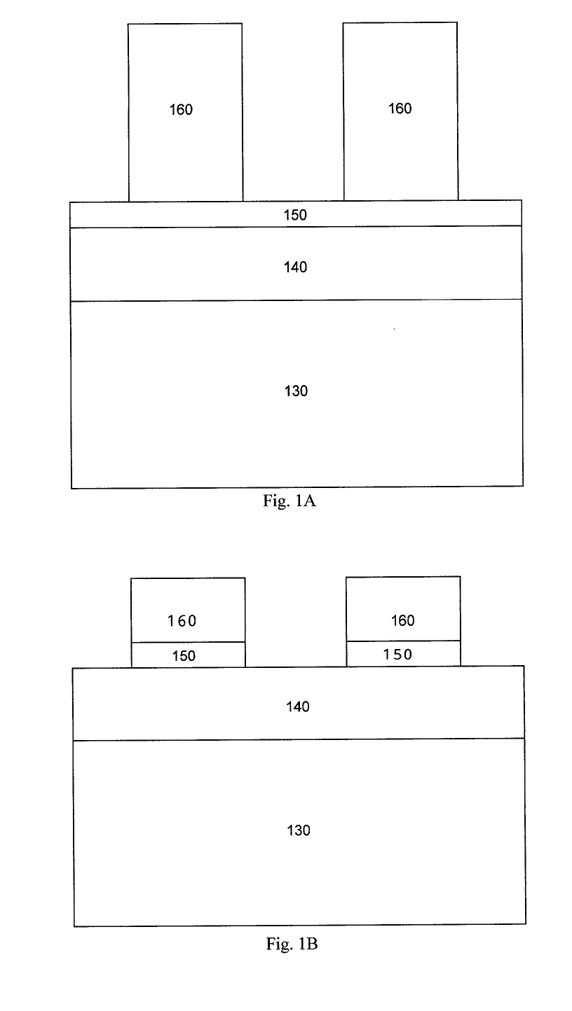

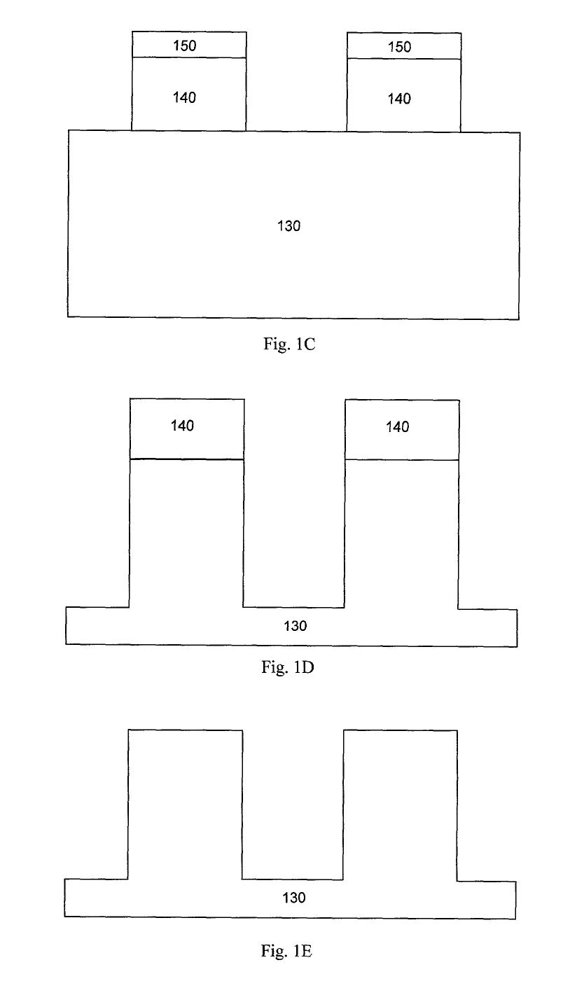

An embodiment of the present invention will now be described in connection with FIGS. 1A-1E. The multilayer structure illustrated in FIG. 1A includes a layer of material 130 to be etched, a chemical vapor deposited (CVD) organic layer 140, a dielectric layer 150, and a patterned photoresist layer 160. As will be appreciated upon further reading, the CVD organic layer 140 and the dielectric layer 150 together provide both antireflective and masking functions.

The layer of material 130 to be etched can be essentially any material for which an etch process is known, which has significant selectivity with respect to the CVD organic layer. Preferred materials for layer 130 include silicon-containing materials such as single-crystal silicon, polycrystalline silicon, amorphous silicon, and combinations of the same. The silicon can be either be doped or undoped.

Preferred CVD organic layers 140 for use in the present invention are those that (1) are fabricated using plasma enhanced chemical vapor deposition (PECVD) and (2) comprise carbon, hydrogen and, optionally, nitrogen. For example, the CVD organic layer can preferably contain 50-85% C, 10-50% H and 0-15% N. More preferably, the CVD organic layer contains 70-80% C, 10-20% H and 5-15% N.

CVD organic layers 140 for use in the present invention are preferably made by plasma enhanced chemical vapor deposition using a hydrocarbon gas feed stream, which preferably further contains molecular nitrogen (N₂). A preferred hydrocarbon gas is propylene (H₂C═CHCH₃). Typical deposition temperatures range from 350 to 550° C. In general, higher deposition temperatures result in increased carbon content. Where nitrogen is added, the nitrogen displaces hydrogen, lowering the hydrogen content and increasing the carbon content. Typically, both higher carbon content and higher nitrogen content lead to higher selectivity of the material to be etched (e.g., silicon) with respect to the CVD organic layer.

Numerous PECVD tools known in the art can be used to provide the CVD organic layers 140. Particularly preferred PECVD tools include the Centura DxZ Silane Kit and the Producer Twin Silane Kit both available from Applied Materials, Inc. of Santa Clara, Calif.

Preferred CVD organic layers for use in connection with the present invention are those having an extinction coefficient (k value) that is 0.4 or more at the specific ultraviolet wavelength used for the photolithography process (e.g., 193 nm or 248 nm). At the same time, the CVD organic layers preferably have an extinction coefficient in the visible spectrum of 0.3 or less to avoid difficulties in wafer alignment. Typically, the refractive index (n value) for the CVD organic layers will range from 1.3 to 1.6.

In general, the thickness of the CVD organic layer will be based upon the depth to which the etching is to be conducted and upon the selectivity of the CVD organic layer with respect to the material to be etched. Typical CVD organic layer thicknesses range from 100 to 2000 Angstroms, more typically 250 to 1000 Angstroms.

At present, a CVD organic layer containing 76% C, 15% H and 9% N is preferred for many applications. This CVD organic layer has a polycrystalline-silicon:CVD-organic selectivity that is greater than a conventional dielectric hard mask (e.g., an oxide, nitride or oxynitride hard mask), presently on the order of about 10:1 or greater depending upon the etch recipe, and a silicon-dioxide:CVD-organic selectivity of greater than about 100:1. It also has, for example, a k value of about 0.67 and an n value of about 1.55 at 193 nm. Such a CVD organic layer can be deposited on a substrate (e.g., silicon) by operating a PECVD tool like those described above under the parameters to follow. Pressure: 5-10 Torr. Power: 800-1500 W per 8-inch wafer. Wafer to electrode spacing: 0.25-1.0 inch. Temperature: 350-500° C. Ratio of propylene to nitrogen: 0.1:1 to 1.5:1. If desired, helium can be added for enhanced efficiency.

The CVD organic layer is also desirable in that it is conformal. This is advantageous, for example, in that a long over-etch (i.e., an extended etch of the layer after reaching the endpoint) can be avoided. The CVD organic layer is also an effective etch mask where fluorine-based chemistry (e.g., CF₄-based chemistry) is used, which is, for example, a relatively clean chemistry. Furthermore, the CVD organic layer can be easily stripped in an oxygen-based plasma etching process.

Referring again to FIG. 1A, a dielectric layer 150 is provided over the CVD organic layer 140. This layer can be formed of any appropriate dielectric material. Preferred materials for dielectric layer 150 include silicon dioxide, silicon nitride and silicon oxynitride, with silicon oxynitride (particularly silicon-rich silicon oxynitride) being more preferred. Silicon oxynitride has been used in the semiconductor industry for some time as an antireflective layer in which reflected light levels are reduced by phase shift cancellation.

Effective phase shift cancellation for the purposes of the present invention can be achieved, for example, by providing a layer of silicon oxynitride that is 200-600 Angstroms in thickness for 248 nm lithography or by providing a layer that is 150-500 Angstroms in thickness for 193 nm lithography. Methods of forming silicon oxynitride layers are well known in the art.

When the above silicon oxynitride layer is combined with an absorption layer like the above CVD organic layer, the antireflective properties of the two layers act in concert. The silicon oxynitride layer thickness can be tuned to provide effective phase shift cancellation, while the CVD organic layer composition can be tuned to provide effective absorption. As a result, the two layers provide an overall reflectivity of less than 1% at deep UV wavelengths commonly used for high-resolution photolithography.

Referring back to FIG. 1A, a patterned photoresist layer 160 is provided over the dielectric layer 150. Due to the anti-reflective nature of the CVD organic layer 140 and dielectric layer 150, standing waves are essentially eliminated during resist photolithography, improving the quality of the patterned photoresist layer 160 that is ultimately produced. The material selected for the photoresist layer 160 can be essentially any known photoresist material. Presently, organic photoresist materials available in the art for deep ultraviolet (e.g., 193 nm and 248 nm) photolithography are preferred. One advantage of the present invention, as discussed further below, is that thin photoresist layers (e.g., less than 2500 Angstroms) can be utilized, which allows, for example, for the creation of patterned photoresist layers with very small feature sizes.

Although not illustrated in FIG. 1A, where silicon oxynitride is selected as the dielectric layer 150 material, an additional barrier layer is frequently provided between the dielectric layer 150 and the photoresist layer 160 to avoid nitrogen migration (commonly referred to as “poisoning”) within the resist layer 160. A thin oxide layer (e.g., 50 Angstroms) is frequently employed for this purpose as is known in the art.

After the patterned photoresist layer 160 is provided, the structure of FIG. 1A is etched in a series of steps. Etching may be conducted in any suitable plasma processing apparatus. Preferably, the plasma processing apparatus used provides a high-density plasma, which may be defined as a plasma having a density that typically ranges from about 5×10¹⁰ to about 5×10¹² cm^{-3.} The source of the high-density plasma may be any suitable high-density source, such as electron cyclotron resonance (ECR), helicon resonance, or inductively coupled plasma (ICP) sources. Each of these is currently in use on semiconductor production equipment. The main difference is that ECR and helicon sources employ an external magnetic field to shape and contain the plasma, while inductively coupled plasma sources do not.

As a first etching step, the dielectric layer 150 (and any additional barrier layer such as silicon dioxide) are opened as illustrated in FIG. 1B. For example, where silicon oxynitride is used as the dielectric layer 150, essentially any etching chemistry known in the art for etching silicon oxynitride can be used. Preferred etching chemistries are those that utilize a plasma source gas which includes a halogen containing species, more preferably a fluorine containing species such as CF₄. (These chemistries are also effective for etching that barrier layer that may be present.)

It is noted that, although such processes typically etch the photoresist layer 160 at a faster rate than the silicon oxynitride layer 150, a thin (e.g., 1000-2500 Angstroms) photoresist layer can nonetheless be used, due to the small thickness (e.g., 150-300 Angstroms) of the silicon oxynitride layer. It is further noted that the ability to make use of a thin photoresist layer 160 means that aggressive resist line trim processes can be employed, which might otherwise thin the photoresist to the point of uselessness. In this connection, the photoresist 160 can be trimmed without adversely affecting the underlying CVD organic layer 140, due to the protective presence of the silicon oxynitride layer 150 (i.e., the plasma used to trim the resist does not etch conventional dielectric layers).

After opening the dielectric layer 150, an etching process is conducted to open the organic CVD layer 140 and produce a structure like that illustrated in FIG. 1C. Preferred processes for this purpose include etching processes that have a high selectivity for the organic CVD layer 140 relative to the dielectric layer 150. In general, preferred processes for this step are those that utilize a plasma source gas that includes an oxygen containing species such as O₂. If desired, one or more species that that passivate the sidewalls of the CVD organic layer during the etching process can be included within the plasma source gas. Examples include halogen-containing species, such as HCl, HBr, CH₃Br, CHCl₃, and so forth.

Chemistries based on O₂ and HBr are more preferred as they can have CVD-organic:silicon-oxynitride selectivities of >100:1 and provide adequate sidewall passivation. Note that these selectivity levels allow the CVD organic layer 140 to be many times the thickness of the silicon oxynitride layer 150 if desired. As previously mentioned, the thicker the layer of material 130 to be etched, the thicker the CVD organic layer 140 is required to be.

It is noted that the etching step for the CVD organic layer 140 also typically etches photoresist 160 in a relatively aggressive manner. Hence, the photoresist 160 is substantially removed in this step. (Removal of the photoresist is not problematic at this point due to the high resistance of the silicon oxynitride layer to the etch, which allows the silicon oxynitride layer 150 to act as a mask for the CVD organic layer 140 after photoresist erosion.) In preferred embodiments, any remaining photoresist is removed by subjecting the layer stack to a predetermined amount of over-etching. If desired, however, any remaining photoresist can be removed in a separate process step specifically directed to etching the photoresist.

After the CVD organic layer 140 is opened and any remaining photoresist is removed, layer 130 is then etched as illustrated in FIG. 1D.

As noted above, one preferred material for use in connection with layer 130 is a silicon-containing layer. Where a silicon-containing layer is used, a step is typically performed to break through any native oxide that is formed. This is done with numerous etching chemistries known in the art for etching oxides. Preferred etching chemistries are halogen based etching chemistries, more preferably fluorine based etching chemistries (e.g., chemistries containing CF₄). After etching through any native oxide layer, the silicon-containing layer is then etched using any appropriate chemistry for etching silicon known in the art. Preferred chemistries are halogen-based etching chemistries.

Note that although the silicon oxynitride layer is typically removed in the course of etching the layer 130, the CVD organic layer 140 remains behind and acts as the masking layer for the etching step. This is a desirable result, because removal of silicon oxynitride can potentially present significant processing issue, if present.

Finally, any remaining CVD organic layer 140 is removed to produce the structure illustrated in FIG. 1E. As with the above etching step for the CVD organic layer, a preferred etching chemistry for this step is based upon oxygen-containing species. Unlike the above step, however, no passivation species are called for.

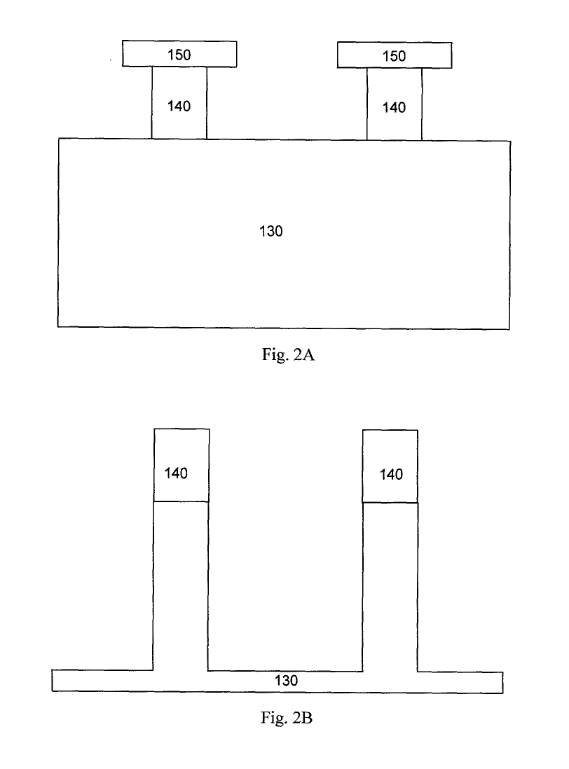

One significant aspect of the present invention is that it effectively allows the CVD organic layer to be trimmed prior to additional processing. For example, after forming the structure of FIG. 1C above, the CVD organic portions 140 of the structure can be trimmed using an etch chemistry that preferentially etches the CVD organic portions 140 relative to the dielectric portions 150. In the specific case where silicon oxynitride is used as the dielectric portions 150, an oxygen-based chemistry (with or without passivating agents) can be used. As a specific example, etching can be conducted using a DPS (decoupled plasma source) series chamber available from Applied Materials, Inc. of Santa Clara, Calif. within the operating parameters to follow: 3-70 mTorr chamber pressure, 300-1800 W source power, 30-300 W bias power, 20-1000 sccm (standard cubic centimeters per minute) O₂, with or without HBr as a passivation gas, to control the degree of trimming rate. After etching, the CVD organic portions 140 take on an appearance like that illustrated in FIG. 2A. This structure can then be processed as discussed in connection with FIG. 1D above, if desired, the resulting structure is shown in FIG. 2B.

Note that by trimming the CVD organic portions, the critical dimensions of the resulting etch features are reduced below those that are provided by the photolithography step. As a specific example, it is noted that photoresist feature sizes of less than 0.13 microns can be provided by currently available 193 nm technology. This photoresist feature size can then be trimmed to about less than 0.07 micron using currently available resist trimming technology, such as O₂-type processes. This results in silicon oxynitride and CVD organic feature sizes of substantially the same size (i.e., less than 0.07 micron). Subsequently, the feature size of the CVD organic layer can be trimmed to about 0.03 micron, or even less, by trimming the CVD organic layer as described above.

It should be further noted that, with the silicon oxynitride layer 150 in place over the CVD organic layer 140, the CVD organic features are trimmed laterally, but not vertically. Thus, excess amounts of CVD organic layer need not be applied before the trimming step to compensate for a loss in thickness during the trimming step. For largely the same reasons, essentially no loss in thickness uniformity of the CVD organic layer occurs during the course of the trimming step.

In some embodiments of the invention, the dielectric layer 150 is not used at all, and the CVD organic layer 140 alone is used to serve as an anti-reflective/masking layer. However, the use of a dielectric layer 150 is preferred based on the numerous advantages discussed above. Without such a dielectric layer 150, for example, a greater resist thickness must typically be used, and some of the CVD organic layer 140 is typically lost during resist stripping using known techniques.

The multilayer anti-reflective hard mask structure of the present invention (i.e., the combination of the dielectric layer and a CVD organic layer) finds beneficial application in many areas, including gate conductor etching processes.

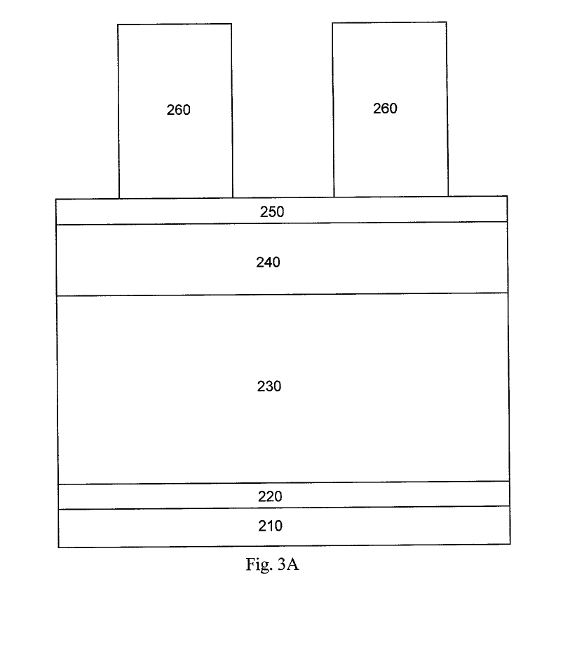

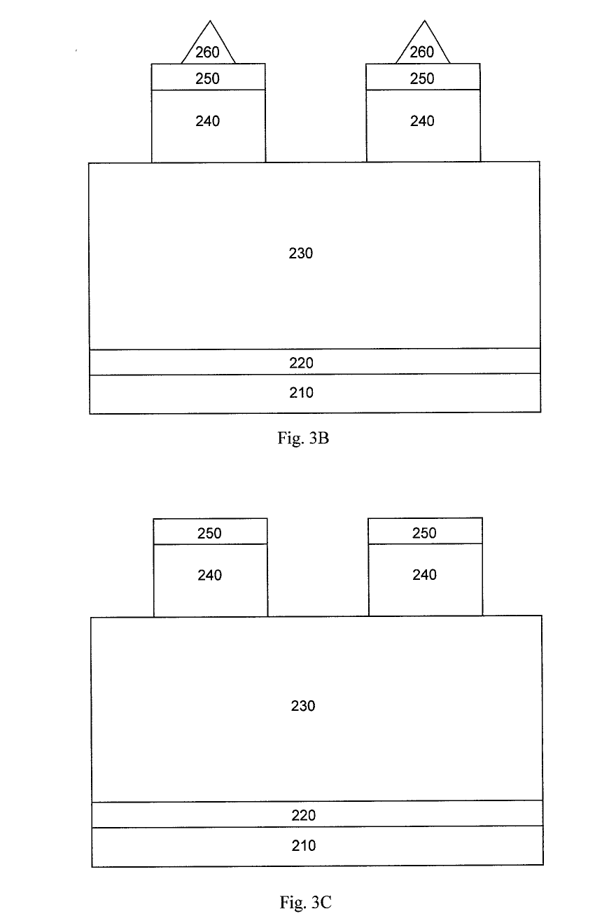

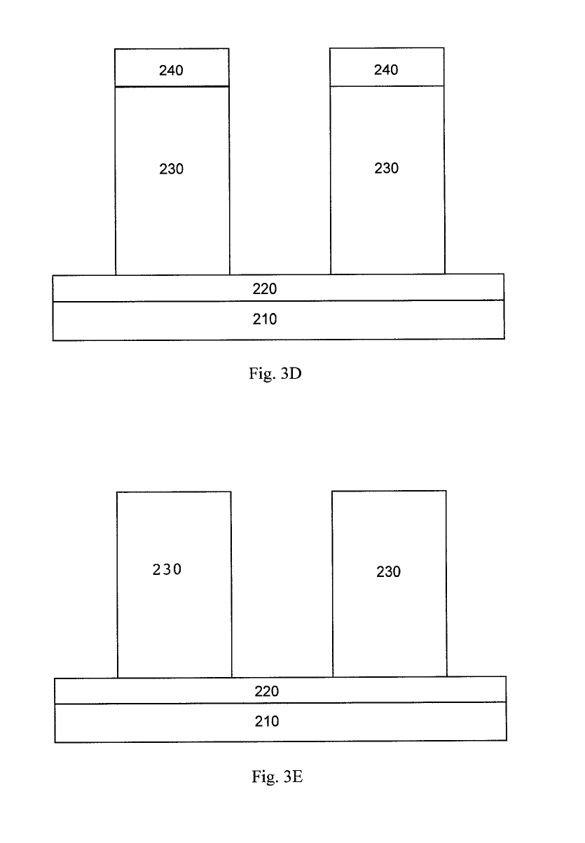

For example, FIG. 3A illustrates a layer stack that includes a semiconductor substrate (preferably a silicon substrate 210), a gate insulator (preferably a gate oxide layer 220), a gate conductor (preferably a doped polycrystalline silicon layer 230), a CVD organic layer 240, a dielectric layer (preferably a silicon oxynitride layer 250) and a patterned photoresist layer 260.

The silicon substrate 210 can be of any appropriate thickness and can be fabricated using any method known in the art.

The gate oxide layer 220 can be any appropriate oxide layer, and is preferably a silicon dioxide layer. The gate oxide layer 220 is typically 10 to 50 Angstroms in thickness and can be provided using any appropriate method known in the art.

The polycrystalline silicon layer 230, which is the layer that is ultimately etched in this embodiment of the invention, is produced by methods well known in the art. This layer has a thickness that preferably ranges, for example, from 500 to 6000 Angstroms, more preferably 1000 to 3000 Angstroms.

The CVD organic layer 240 in this embodiment is produced using the methods discussed above. In this embodiment, the CVD organic layer 240 preferably has a composition of 75-77% C, 14-16% H and 8-10% N, and it preferably has a thickness of 400 to 600 Angstroms.

The silicon oxynitride layer 250 is preferably 150-300 Angstroms in thickness as discussed above.

The patterned photoresist layer 260 in this embodiment can be essentially any organic photoresist material available in the art for deep ultraviolet photolithography. In one specific preferred embodiment, the photoresist layer is a TOK P308 resist layer (appropriate for 248 nm lithography), which is preferably applied in a thickness of 2000 to 3000 Angstroms.

Although not illustrated, a silicon dioxide barrier layer is preferably provided between the silicon oxynitride layer 250 and the photoresist layer 260 as is well known in the art. The barrier layer is typically 40 to 60 Angstroms in thickness.

After establishing the structure of FIG. 3A, the barrier layer and the underlying silicon oxynitride layer 250 are opened as discussed above. In a specific preferred process, the structure of FIG. 3A is etched within a DPS (decoupled plasma source) series chamber available from Applied Materials, Inc. of Santa Clara, Calif. within the operating parameters to follow. Etching gases: 40-110 sccm (standard cubic feet per minute) CF₄ and 40-110 sccm Ar. Pressure: 2-6 mTorr. Source power: 250-750 W. Bias power: 20-60 W. Pedestal temperature: 50° C. Wall temperature: 65° C. Dome temperature: 80° C. Etching is terminated by observing the emission spectrum at 3865 Angstroms, which will drop significantly after reaching the CVD organic layer, and subsequently conducting a 40% over etch (i.e., continuing etch for 40% of the time that led up to the observed change in the emission spectrum).

The CVD organic layer 240 is then opened as discussed above. One specific preferred process, using a DPS-series chamber, is as follows. Etching gases: 9-27 sccm O₂, 20-60 sccm HBr, and 20-60 sccm Argon. Pressure: 2-6 mTorr. Source power: 500-1500 W. Bias power: 75-225 W. Pedestal temperature: 50° C. Wall temperature: 65° C. Dome temperature: 80° C. Etching is complete upon observation of a significant decrease in the emission spectrum at 4835 Angstroms, which will occur after reaching the native oxide on the polycrystalline silicon surface.

The resulting structure is illustrated in FIG. 3B. As can be seen from this figure, the photoresist is largely consumed at this point. Any remaining photoresist can be removed at this point using numerous photoresist-stripping techniques known in the art. In one preferred embodiment of the invention, the photoresist is removed simply by continuing with the O₂ etching procedure of the prior step after the 4835 Angstrom end-point is detected (e.g., for 15-15 seconds). This procedure also effectively serves as an over-etch for the CVD organic layer 240. The resulting structure is illustrated in FIG. 3C.

Next, a step is conducted to break through the native oxide found on the polycrystalline silicon layer 230 as discussed above. One specific preferred process, using a DPS-series chamber, follows. Etching gas: 50-120 sccm CF₄. Pressure: 5-15 mTorr. Source power: 300-900 W. Bias power: 50-130 W. Pedestal temperature: 50° C. Wall temperature: 65° C. Dome temperature: 80° C. Due to both the thinness of the oxide and the relative aggressiveness of the etch process, etching is terminated after a short time period, e.g., 5-15 seconds.

Subsequently, the polycrystalline silicon layer 230 is subjected to an etching step (or multiple etching steps) in which it is etched down to the oxide layer 220 as illustrated in FIG. 3D. As noted above, this etching step can be based on any appropriate chemistry for etching silicon, with halogen-based systems being preferred as discussed above. As also noted above, this step typically removes the silicon oxynitride layer 250 as shown.

In a particularly preferred embodiment, a relatively more aggressive etching step (for example, an etching step having a polycrystalline silicon:oxide selectivity ranging from 3:1 to 4:1) is first performed to etch through most of the polycrystalline silicon layer 230. One specific preferred process, using a DPS-series chamber, follows. Etching gases: 15-35 sccm CF₄, 50-150 sccm HBr, 30-90 sccm Cl₂ and 6-18 sccm HeO₂ (i.e., a mixture of 70% He and 30% O₂). Pressure: 2-6 mTorr. Source power: 500-1300. Bias power: 40-120 W. Pedestal temperature: 50° C. Wall temperature: 65° C. Dome temperature: 80° C.

Subsequently, a relatively less aggressive step (for example, an etching step having a polycrystalline silicon:oxide selectivity of >20:1) is then conducted until the oxide layer is reached. This is sometimes referred to in the art as a “soft landing” step. One specific preferred process, using a DPS-series chamber, follows. Etching gases: 50-150 sccm HBr, 5-15 sccm Cl₂ and 6-18 sccm HeO₂. Pressure: 15-35 mTorr. Source power: 400-1100 W. Bias power: 40-120 W. Pedestal temperature: 50° C. Wall temperature: 65° C. Dome temperature: 80° C. Etching is terminated by observing the emission spectrum at 2880 Angstroms, which will decrease significantly after reaching the gate oxide layer 220.

At this point, any remaining polycrystalline silicon on the oxide is cleaned up with an even less aggressive over-etch step (for example, an etching step having a polycrystalline silicon:oxide selectivity of >100:1). One specific preferred process, using a DPS-series chamber, follows. Etching gases: 60-180 sccm HBr and 3-9 sccm HeO₂. Pressure: 40-100 mTorr. Source power: 350-1050 W. Bias power: 40-90 W. Pedestal temperature: 50° C. Wall temperature: 65° C. Dome temperature: 80° C. This step is conducted, for example, for 30-60 seconds.

Finally, an etching step is performed to remove the remaining CVD organic layer 240 and produce the structure of FIG. 3E. As discussed above, a preferred etching chemistry for this step is an oxygen-based chemistry. One specific preferred process, using a Gasonics plasma etching tool, follows. Etching gases: 500-1500 sccm O₂ and 50-150 sccm N₂. Pressure: 600-1800 mTorr. Source power: 500-1500 W. Pedestal temperature: 250° C. This step is conducted, for example, for 80-160 seconds.

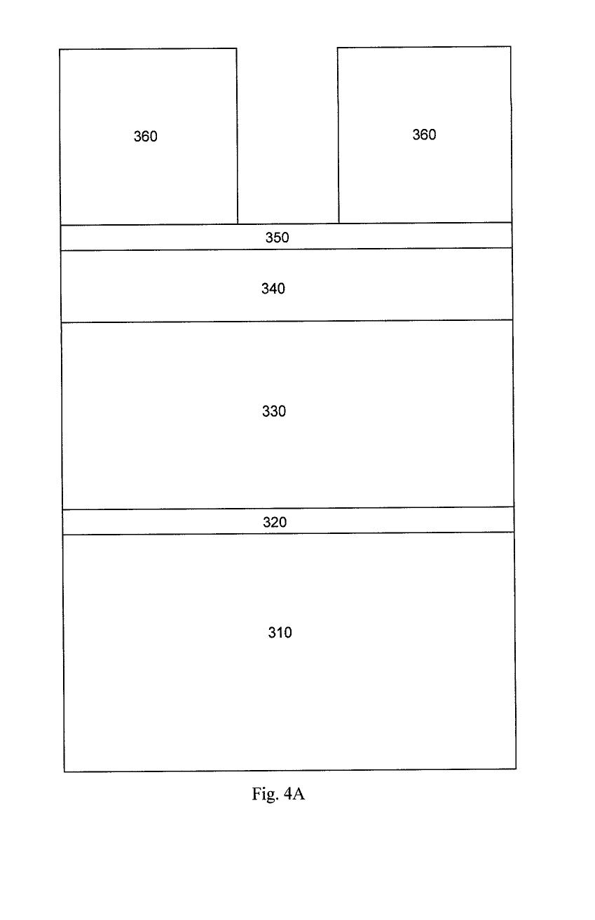

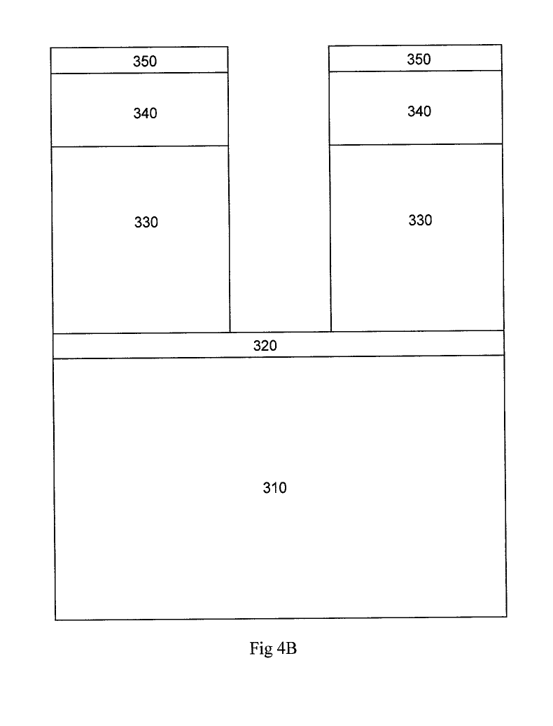

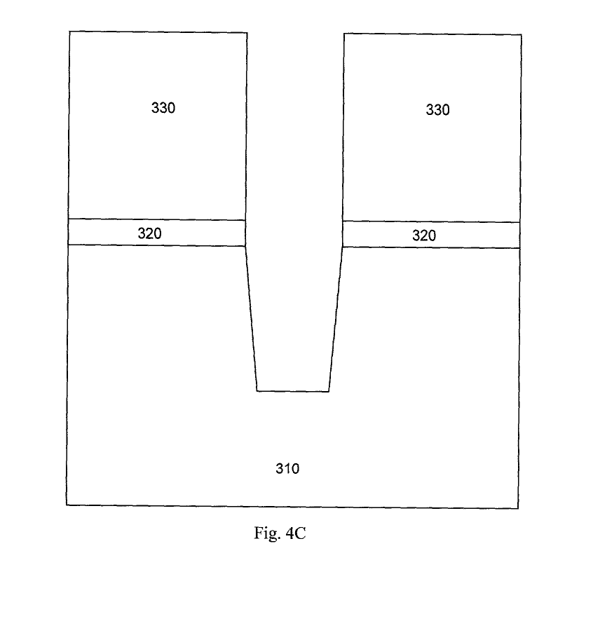

The multilayer anti-reflective hard mask structure of the present invention also finds beneficial application in the area of shallow trench isolation etching (commonly referred to as “STI” etching). FIG. 4A illustrates a structure useful in the art of STI etching. This structure includes a semiconductor substrate 310 (e.g., a silicon substrate), a pad oxide layer 320 (e.g., a silicon dioxide layer), a silicon nitride layer 330, a CVD organic layer 340, a dielectric layer (preferably a silicon oxynitride layer 350) and a patterned photoresist layer 360.

The silicon substrate 310 can be of any appropriate thickness and can be fabricated using any method known in the art. The pad oxide layer 320 can be any appropriate oxide layer (e.g., a silicon dioxide layer) and can be fabricated using any method known in the art. The silicon nitride layer 330 is produced by methods known in the art and has a thickness that preferably ranges, for example, from 1000 to 2000 Angstroms.

The CVD organic layer 340 in this embodiment preferably has a composition of 75-77% C, 14-16% H and 8-10% N and is formed as discussed above. The CVD organic layer beneficially has a thickness of 300 to 400 Angstroms. The silicon oxynitride layer 350 beneficially has a thickness of 125-175 Angstroms.

The patterned photoresist layer 360 can be essentially any organic photoresist material available in the art for deep ultraviolet photolithography, and ranges, for example, from 3000-4000 Angstroms in thickness.

Although not illustrated, a silicon dioxide barrier layer (e.g., a 40 to 60 Angstrom thick layer) is preferably provided between the silicon oxynitride layer 350 and the photoresist layer 360.

After establishing the structure of FIG. 4A, any barrier layer and the underlying silicon oxynitride layer 350 are opened as discussed above. The CVD organic layer 340 is then opened, also as discussed above, and etching is continued to open up the silicon nitride layer 330. At this point, any remaining photoresist is stripped as discussed above to provide the structure of FIG. 4B.

Subsequently, a step is conducted to break through the pad oxide layer 320 that is similar to that discussed above for etching through native oxide. After breakthrough of the pad oxide layer 320, the silicon layer is etched to a desired depth, preferably using a halogen-based etching process. More preferably, the silicon is etched to a desired depth as is known in the art using a relatively more aggressive etching step, followed by a relatively less aggressive “softclean” etching step to remove the etch byproduct coating inside the etch tool. Finally, the remnants of the CVD organic layer are removed using a process like that discussed above to produce the structure of FIG. 4C. As seen from this figure, the trench is typically etched such that a tapered trench profile (e.g., 75 to 89 degrees) is produced.

Relative to traditional photoresist-based STI etching processes, the above process provides, among other advantages, better profile and etch rate microloading, higher etch rates, better photoresist profile (largely due to the fact that the resist has been removed at the start of the silicon etch), and no photoresist budget issues. On the other hand, the above process provides, relative to prior art in-situ and ex-situ hard-mask STI processes, the advantage of essentially no nitride loss, among others.

Although various embodiments are specifically illustrated and described herein, it will be appreciated that modifications and variations of the present invention are covered by the above teachings and are within the purview of the appended claims without departing from the spirit and intended scope of the invention.

All the features disclosed in this specification (including any accompanying claims, abstract and drawings), and/or all of the steps of any method or process so disclosed, may be combined in any combination, except for combinations where at least some of the features and/or steps are mutually exclusive.

Each feature disclosed in this specification (including any accompanying claims, abstract, and drawings), may be replaced by alternative features serving the same equivalent or similar purpose, unless expressly stated otherwise. Thus, unless expressly stated otherwise, each feature disclosed is one example only of a generic series of equivalent or similar features.

In the claims:

1. A multilayer antireflective hard mask structure comprising:
a CVD organic layer, said CVD organic layer comprising carbon and hydrogen; and
a dielectric layer over said CVD organic layer.

2. The multilayer antireflective hard mask structure of claim 1, wherein said dielectric layer is a silicon oxynitride layer.

3. The multilayer antireflective hard mask structure of claim 1, wherein said CVD organic layer comprises less than 1% nitrogen.

4. The multilayer antireflective hard mask structure of claim 1, wherein said CVD organic layer comprises more than 1% nitrogen.

5. The multilayer antireflective hard mask structure of claim 4, wherein said CVD organic layer comprises 70-80% carbon, 10-20% hydrogen and 5-15% nitrogen.

6. The multilayer antireflective hard mask structure of claim 1, wherein said dielectric layer is a silicon oxynitride layer and wherein said CVD organic layer comprises 70-80% carbon, 10-20% hydrogen and 5-15% nitrogen.

7. The multilayer antireflective hard mask structure of claim 6, wherein said dielectric layer ranges from 150 to 500 Angstroms in thickness.

8. A method of forming a multilayer antireflective hard mask structure, said method comprising:
providing a substrate structure;
depositing a CVD organic layer over said substrate structure, said CVD organic layer comprising carbon and hydrogen;
depositing a dielectric layer over said CVD organic layer;
providing a patterned organic photoresist layer over said dielectric layer;
etching said dielectric layer through apertures in said patterned photoresist layer in a first plasma etching step until apertures are formed in said dielectric layer; and
etching said CVD organic layer through said apertures in said dielectric layer in a second plasma etching step until apertures are formed in said CVD organic layer.

9. The method of claim 8, wherein said dielectric layer is a silicon oxynitride layer.

10. The method of claim 9, wherein said first plasma etching step is conducted using a plasma source gas that comprises a halogen containing species.

11. The method of claim 10, wherein said first plasma etching step is conducted using a plasma source gas that comprises a fluorocarbon containing species.

12. The method of claim 8, wherein said CVD organic layer is deposited by a plasma enhanced chemical vapor deposition process using a feed stream that comprises a hydrocarbon species.

13. The method of claim 12, wherein said hydrocarbon species is propylene gas.

14. The method of claim 12, wherein said feed stream further comprises N₂ gas.

15. The method of claim 8, wherein said second plasma etching step is conducted using a plasma source gas that comprises an oxygen containing species.

16. The method of claim 15, wherein said oxygen containing species is O₂.

17. A method of etching a substrate structure comprising:
providing a substrate structure;
providing a patterned multilayer mask structure over said substrate structure, said patterned multilayer mask structure having apertures and comprising: (a) a CVD organic layer comprising carbon and hydrogen and (b) a dielectric layer over said CVD organic layer; and
etching said substrate structure through said apertures by a plasma etching process.

18. The method of claim 17, further comprising removing remnants of said CVD organic layer after said substrate structure is etched.

19. The method of claim 18, wherein said remnants are removed by a plasma etching process in the presence of a plasma source gas that comprises an oxygen containing species.

20. The method of claim 19, wherein said oxygen containing species is O₂.

21. The method of claim 17, wherein said substrate structure comprises a silicon layer and wherein said silicon layer is etched in the course of said plasma etching process.

22. The method of claim 21, wherein said plasma etching process comprises a plasma etching step that utilizes a plasma source gas composition comprising a halogen containing species.

23. The method of claim 21,
wherein said substrate structure comprises a single crystal silicon layer, an oxide layer over said single crystal silicon layer, a doped polycrystalline silicon layer over said oxide layer and a native oxide layer over said doped polycrystalline silicon layer, and
wherein said native oxide layer and said doped polycrystalline silicon layer are etched by said plasma etching process.

24. The method of claim 23, wherein said plasma etching process comprises two or more plasma etching steps and wherein each of the two or more plasma etching steps utilizes a plasma source gas composition that comprises a halogen containing species.

25. The method of claim 21,
wherein said substrate structure comprises a single crystal silicon layer, an oxide layer over said single crystal silicon layer and a silicon nitride layer over said oxide layer, and
wherein said single crystal silicon layer, said oxide layer, and said silicon nitride layer are etched by said plasma etching process.

26. The method of claim 25, wherein said plasma etching process comprises (a) one or more plasma etching steps that utilize a plasma source gas composition comprising a oxygen containing species and (b) one or more plasma etching steps that utilize a plasma source gas composition comprising a halogen containing species.

27. A method of etching a substrate structure comprising:
providing a substrate structure;
providing a CVD organic layer comprising carbon and hydrogen over said substrate structure, said CVD organic layer having apertures therein; and
etching said substrate structure through said apertures by a plasma etching process.

28. The method of claim 27, further comprising removing remnants of said CVD organic layer after said substrate structure is etched by a plasma etching process in the presence of a plasma source gas that comprises an oxygen containing species.

29. The method of claim 28, wherein said oxygen containing species is O₂.

30. A method for trimming a mask feature comprising:
providing one or more mask features on a substrate structure, each said mask feature comprising (a) a CVD organic layer comprising carbon and hydrogen, and (b) a dielectric layer disposed over said CVD organic layer such that sidewall portions of said CVD organic layer are exposed; and
etching said exposed sidewall portions of said CVD organic layer by means of a plasma etching process such that the width of said one or more mask features is reduced at said substrate.

31. The method of claim 30, wherein said dielectric layer is a silicon oxynitride layer.

32. The method of claim 30, wherein said CVD organic layer comprises 70-80% carbon, 10-20% hydrogen and 5-15% nitrogen.

33. The method of claim 30, wherein said CVD organic layer is etched using a plasma source gas that comprises an oxygen containing species.

34. The method of claim 33, wherein said oxygen containing species is O₂.
